(19) United States
(12) Patent Application Publication
(10) Pub. No.: US 2025/0201597 A1
(43) Pub. Date: Jun. 19, 2025

(54) LAMINATING DEVICE AND METHOD OF FABRICATING SEMICONDUCTOR CHIP USING THE SAME

(71) Applicant: SAMSUNG ELECTRONICS CO., LTD., SUWON-SI (KR)

(72) Inventors: YEONG JUN JO, Suwon-si (KR); YEOI WON SEO, Suwon-si (KR); JAE IL JEONG, Suwon-si (KR); JWA HYEON KIM, Suwon-si (KR)

(21) Appl. No.: 18/733,210

(22) Filed: Jun. 4, 2024

(30) Foreign Application Priority Data
Dec. 13, 2023 (KR) 10-2023-0180368

(51) Int. Cl. H01L 21/67; H01L 21/304; H01L 21/683; H01L 21/78

(52) U.S. Cl. CPC H01L 21/67132; H01L 21/304; H01L 21/67092; H01L 21/67253; H01L 21/6836; H01L 21/78; H01L 2221/68327

(57) ABSTRACT

A laminating device that prevents defects in a semiconductor chip caused by tension imbalance includes a substrate support on which a target substrate is disposed, a guide table that surrounds a circumference of the target substrate, and a press roller that attaches a lamination tape by pressing the lamination tape against upper surfaces of the target substrate and the guide table. The guide table includes plurality of vacuum holes that adsorb the lamination tape.

### CROSS-REFERENCE TO RELATED APPLICATION

This application claims priority under 35 U.S.C. 119 from Korean Patent Application No. 10-2023-0180368, filed on Dec. 13, 2023 in the Korean Intellectual Property Office, the contents of which are herein incorporated by reference in their entirety.

### TECHNICAL FIELD

Embodiments of the present disclosure are directed to a laminating device and a method of fabricating a semiconductor chip using the same.

### DISCUSSION OF THE RELATED ART

As part of a semiconductor chip manufacturing process, a back grinding process is performed to grind the back of a wafer with integrated circuits (ICs) formed thereon, to process the wafer to a desired thickness. In addition, to perform the back grinding process, a lamination process is performed to protect the front of the wafer, where the ICs are actually formed, from particles, etc. The lamination process may include pressing a lamination tape against the front of the wafer using a press roller to attach the lamination tape and the wafer together, and trimming the lamination tape to the size of the wafer.

However, during the lamination process, abnormal conditions such as warping of the wafer and/or warping of the press roller can occur, leading to defects in semiconductor chips by causing a tension imbalance in the lamination tape.

### SUMMARY

Embodiments of the present disclosure provide a laminating device that can prevent defects in a semiconductor chip caused by a tension imbalance.

Embodiments of the present disclosure also provide a method for manufacturing semiconductor chip with an improved yield.

According to an embodiment of the present disclosure, there is provided a laminating device that includes a substrate support on which a target substrate is disposed, a guide table that surrounds a circumference of the target substrate, and a press roller that attaches a lamination tape by pressing the lamination tape against upper surfaces of the target substrate and the guide table. The guide table includes plurality of vacuum holes that adsorb the lamination tape.

According to an embodiment of the present disclosure, there is provided a laminating device that includes a substrate support on which a target substrate is disposed, a guide table that surrounds a circumference of the target substrate, a press roller that attaches a lamination tape onto upper surfaces of the target substrate and the guide table by pressing an upper surface of the lamination tape while moving in a first direction parallel to the upper surface of the target substrate, and clamping members that clamp both sides of the lamination tape in a second direction parallel to the upper surface of the target substrate and that crosses the first direction. The guide table includes a plurality of vacuum holes that extend from the upper surface of the guide table and provide a negative pressure, and the clamping members operate in conjunction with the press roller.

According to an embodiment of the present disclosure, there is provided a method of fabricating a semiconductor chip that includes providing a semiconductor substrate that includes first and second surfaces that are opposite to each other, forming a semiconductor device layer on the first surface of the semiconductor substrate, forming a lamination tape that covers the semiconductor device layer by using a laminating device, performing a stealth dicing process on the semiconductor substrate and the semiconductor device layer, and performing a grinding process on the second surface of the semiconductor substrate. The laminating device includes a wafer table on which the semiconductor substrate is disposed, a guide table that surrounds a circumference of the semiconductor substrate, and a press roller that attaches a lamination tape by pressing the lamination tape against upper surfaces of the target substrate and the guide table. The guide table includes a plurality of vacuum holes that adsorb the lamination tape.

### BRIEF DESCRIPTION OF THE DRAWINGS

FIG. 1 is a perspective view of a laminating device according to some embodiments of the present disclosure.

FIGS. 2 and 3 are cross-sectional views of a laminating device of FIG. 1.

FIG. 4 is a plan view of a laminating device of FIG. 1.

FIGS. 5 to 8 illustrate the effects of a laminating device according to some embodiments of the present disclosure.

FIG. 9 is a plan view of a laminating device according to some embodiments of the present disclosure.

FIG. 10 is a plan view of a laminating device according to some embodiments of the present disclosure.

FIG. 11 is a perspective view of a laminating device according to some embodiments of the present disclosure.

FIG. 12 is a cross-sectional view of a laminating device of FIG. 11.

FIG. 13 are cross-sectional views that illustrate an operation of a laminating device of FIG. 11.

FIG. 14 is a cross-sectional view of a laminating device according to some embodiments of the present disclosure.

FIG. 15 is a cross-sectional view of a laminating device of FIG. 14.

FIG. 16 are cross-sectional views that illustrate operation of a laminating device of FIG. 14.

FIGS. 17 to 20 are cross-sectional views that illustrate a method of fabricating a semiconductor chip according to some embodiments of the present disclosure.

### DETAILED DESCRIPTION

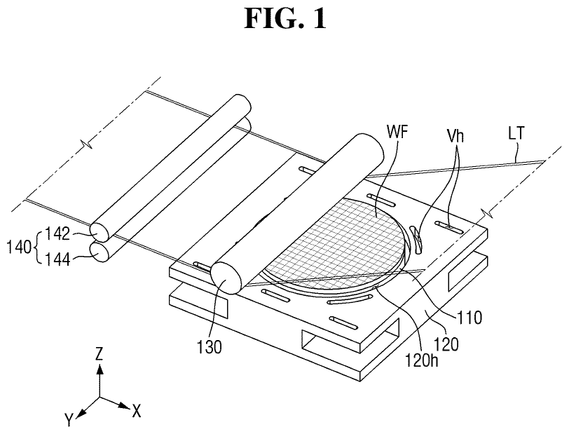

Laminating devices according to some embodiments of the present disclosure will hereinafter be described with reference to FIGS. 1 to 16.

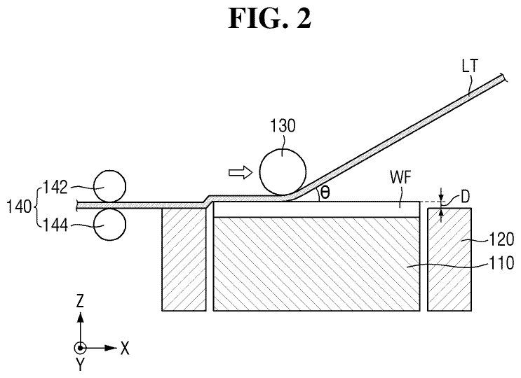

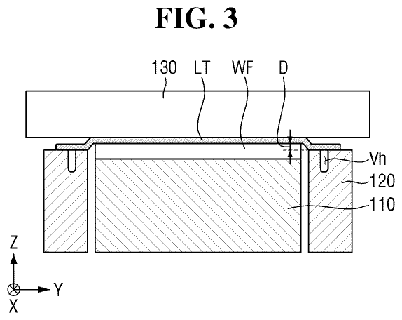

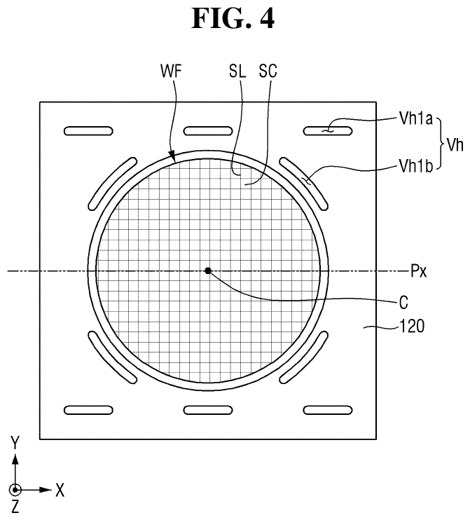

FIG. 1 is a perspective view of a laminating device according to some embodiments of the present disclosure. FIGS. 2 and 3 are cross-sectional views of a laminating device of FIG. 1. FIG. 4 is a plan view of a laminating device of FIG. 1.

Referring to FIGS. 1 to 4, a laminating device according to some embodiments of the present disclosure includes a substrate support 110, a guide table 120, and a press roller 130. In some embodiments, the laminating device further includes a guide roller 140.

The substrate support 110 supports a target substrate WF. For example, the target substrate WF is disposed on the upper surface of the substrate support 110. The substrate support 110 may be, for example, a cylindrical structure, but embodiments of the present disclosure are not necessarily limited thereto. The substrate support 110 can be elevated and/or rotated, if necessary. The target substrate WF on the substrate support 110 may be, for example, a wafer or a printed circuit board (PCB), but embodiments of the present disclosure are not necessarily limited thereto.

In some embodiments, the target substrate WF is a wafer that includes a plurality of chip areas SC. Various types of individual devices can be formed in each of the chip areas SC. Each of the chip areas SC is defined by scribe lines SL. For example, the scribe lines SL extend along a first direction X and a second direction Y and surround each of the chip areas SC. The first and second directions X and Y are parallel to an upper surface of the target substrate WF and cross each other, for example, at right angles. The chip areas SC are separated from each other by a die sawing process performed along the scribe lines SL.

The guide table 120 surrounds the circumference of the target substrate WF on the substrate support 110. For example, the guide table 120 includes an inner hole 120h that accommodates the target substrate WF. A shape of the inner hole 120h corresponds to the outer circumference of the target substrate WF. For example, if the target substrate WF is a disc-shaped wafer, the inner hole 120h has a cylindrical shape.

The guide table 120 is illustrated as being disposed on one side of the substrate support 110, but embodiments of the present disclosure are not necessarily limited thereto. In some embodiments, the diameter of the substrate support 110 is greater than the diameter of the target substrate WF, and the guide table 120 is disposed on the upper surface of the substrate support 110 to surround the target substrate WF.

In some embodiments, the upper surface of the guide table 120 is disposed lower than the upper surface of the target substrate WF on the substrate support 110. A height difference D between the upper surface of the guide table 120 and the upper surface of the target substrate WF is, for example, between about 50 μm and about 100 μm. The height difference D transfers pressure that attaches a lamination tape LT onto the target substrate WF.

The press roller 130 is disposed on the target substrate WF and the guide table 120. The press roller 130 presses the lamination tape LT against, and attaches the lamination tape LT onto, the upper surfaces of the target substrate WF and the guide table 120. For example, lamination tape LT with a predetermined inclination angle θ relative to the upper surface of the target substrate WF is provided on the upper surfaces of the target substrate WF and the guide table 120. The press roller 130 presses the upper surface of the lamination tape LT while moving from one side to the other side of the guide table 120. For example, the press roller 130 has a rotational axis that extends along the second direction Y and presses the upper surface of the lamination tape LT while moving in the first direction X. As a result, the lamination tape LT is attached to the upper surfaces of the target substrate WF and the guide table 120.

The lamination tape LT is attached to the target substrate WF to protect the surface of the target substrate WF. For example, the target substrate WF is a wafer with a semiconductor device layer formed thereon. The lamination tape LT is attached to the semiconductor device layer to protect the semiconductor device layer in subsequent processes.

The guide table 120 is attached to the lamination tape LT together with the target substrate WF. During the attachment of the lamination tape LT to the target substrate WF, the guide table 120 fixes the outer edges of the lamination tape LT. Consequently, tension imbalance in the lamination tape LT is reduced.

The guide roller 140 is disposed on one side of the guide table 120. For example, the guide roller 140 and the guide table 120 are arranged along the first direction X. The guide roller 140 guides the lamination tape LT provided on the upper surfaces of the target substrate WF and the guide table 120. In addition, the guide roller 140 may also collect the lamination tape LT that remains after being attached to the target substrate WF. For example, the lamination tape LT attached to the target substrate WF is cut to fit the size of the target substrate WF by a cutter. Then, the remaining lamination tape LT is moved by the guide roller 140 in a direction opposite to the first direction X.

In some embodiments, the guide roller 140 includes a first roller 142 on the upper surface of the lamination tape LT and a second roller 144 on the lower surface of the lamination tape LT. Each of the first and second rollers 142 and 144 has a rotational axis that extends in the second direction Y. Furthermore, the first and second rollers 142 and 144 rotate in opposite directions. The lamination tape LT is interposed and guided or collected between the first and second rollers 142 and 144.

The guide table 120 includes a plurality of vacuum holes Vh. Each of the vacuum holes Vh adsorbs the lamination tape LT disposed on the guide table 120 by providing a negative pressure, such as a vacuum pressure. For example, each of the vacuum holes Vh extends into the guide table 120 from the upper surface of the guide table 120 and is connected to a vacuum pump that provides the vacuum pressure. Thus, the lamination tape LT disposed on the upper surface of the guide table 120 is adsorbed by each of the vacuum holes Vh. The vacuum holes Vh enhance the adhesion between the guide table 120 and the lamination tape LT. The negative pressure, such as the vacuum pressure, provided to the vacuum holes Vh is, for example, between about −50 kPA and about −70 kPA.

In some embodiments, the vacuum holes Vh are symmetrically arranged in the second direction Y. For example, as illustrated in FIG. 4, a reference line Px is defined that extends in the first direction X and passes through a center C of the target substrate WF. In a plan view, the vacuum holes Vh are symmetrically arranged with respect to the reference line Px. The vacuum holes Vh can effectively prevent tension imbalance in the lamination tape LT in the second direction Y.

The vacuum holes Vh are illustrated as being symmetrically arranged in the first direction X, but embodiments of the present disclosure are not necessarily limited thereto. In some embodiments, the vacuum holes Vh are not symmetrically arranged in the first direction X.

In some embodiments, the vacuum holes Vh include a plurality of first sub-holes Vh1a and a plurality of second sub-holes Vh1b. The first sub-holes Vh1a are arranged in a line along the first direction X. The second sub-holes Vh1b are arranged along the circumference of the target substrate WF or the inner hole 120h. The first sub-holes Vh1a and the second sub-holes Vh1b are both symmetrically arranged in the second direction Y.

In some embodiments, in a plan view, each of the first sub-holes Vh1a has a linear shape that extends lengthwise in the first direction X. In some embodiments, in a plan view, each of the second sub-holes Vh1b has an arc shape that extends along part of the circumference of the target substrate WF or the inner hole 120h.

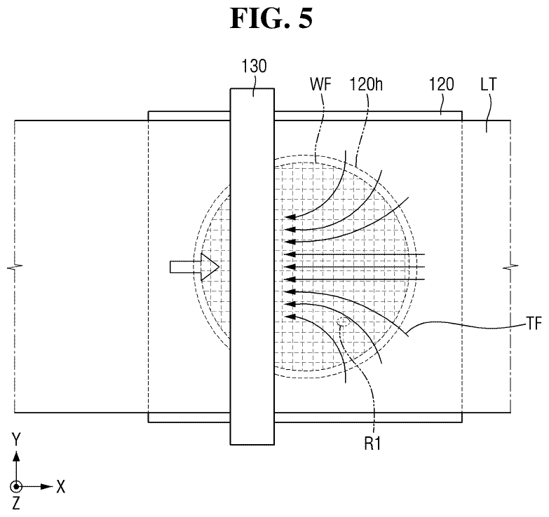

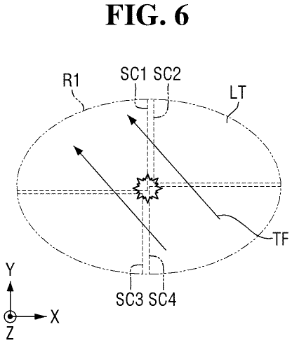

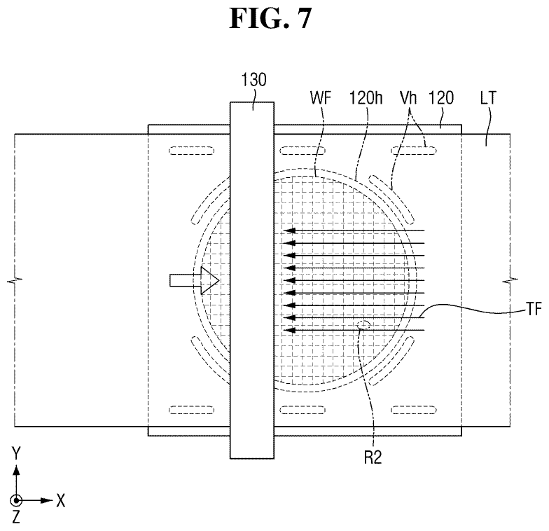

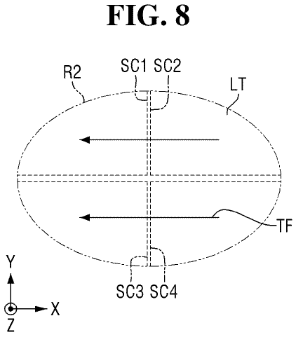

FIGS. 5 to 8 illustrate effects of a laminating device according to some embodiments of the present disclosure. For convenience, repeated descriptions of components described above with reference to FIGS. 1 to 4 may be summarized or omitted. For reference, FIG. 6 is an enlarged plan view of a R1 area of FIG. 5, and FIG. 8 is an enlarged plan view of a R2 area of FIG. 7.

During a lamination process using the guide table 120 and the press roller 130, tension with components, hereinafter the first-direction components, in the direction of movement of the press roller 130 can occur in the lamination tape LT. However, due to warping of the target substrate WF and/or the press roller 130, the lamination tape LT might not properly attach to the guide table 120, resulting in a tension imbalance in the lamination tape LT. For example, the lamination tape LT might not fully attach to the guide table 120 in the second direction Y, and the tension that occurs in the lamination tape LT can have components, hereinafter the second-direction components, perpendicular to the direction of movement of the press roller 130. For example, as illustrated in FIG. 5, tension flows TF form in the lamination tape LT in a diagonal direction with both first-direction components and second-direction components, such as a direction between the first and second directions X and Y.

The tension flows TF can potentially cause defects in the target substrate WF. For example, as illustrated in FIG. 6, the target substrate WF includes first to fourth chip areas SC1 to SC4. For example, the first and second chip areas SC1 and SC2 are adjacent in the first direction X. The first and third chip areas SC1 and SC3 are adjacent in the second direction Y. The second and fourth chip areas SC2 and SC4 are adjacent in the second direction Y, and the third and fourth chip areas SC3 and SC4 are adjacent in the first direction X. For example, the first and fourth chip areas SC1 and SC4 are adjacent in a diagonal direction between the first and second directions X and Y. The tension flows TF formed in the diagonal direction can cause a collision between the first and fourth chip areas SC1 and SC4 leading to corner cracks in the first chip area SC1 and/or the fourth chip area SC4.

A laminating device according to some embodiments of the present disclosure can effectively prevent tension imbalance in the lamination tape by using the guide table 120 with a plurality of vacuum holes Vh. For example, as mentioned above, each of the vacuum holes Vh can adsorb the lamination tape LT disposed on the guide table 120, thereby strengthening the adhesion between the guide table 120 and the lamination tape LT. Therefore, a laminating device is provided that can prevent defects in the target substrate WF that may be caused by tension imbalance.

Moreover, as described above, the vacuum holes Vh are symmetrically arranged in the second direction Y. The vacuum holes Vh can more effectively prevent defects in the target substrate WF by suppressing the second-direction components of the tension flows TF. For example, vacuum holes Vh that are symmetrically arranged in the second direction Y as illustrated in FIGS. 7 and 8 can prevent a collision between the first and fourth chip areas SC1 and SC4 by suppressing the second-direction components of the tension flows TF.

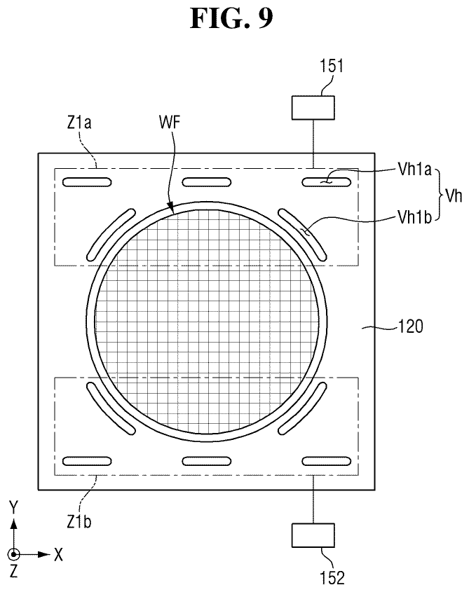

FIG. 9 is a plan view of a laminating device according to some embodiments of the present disclosure. For convenience, repeated descriptions of components described above with reference to FIGS. 1 to 8 may be summarized or omitted.

Referring to FIG. 9, a laminating device according to some embodiments of the present disclosure includes one or more pressure sensors (151 and 152).

The pressure sensors (151 and 152) can detect the pressure in at least some of a plurality of vacuum holes Vh. For example, the pressure sensors (151 and 152) include one or more vacuum sensors that can detect the negative pressure, such as a vacuum pressure, provided to the vacuum holes Vh.

In some embodiments, the pressure sensors (151 and 152) include first and second pressure sensors 151 and 152 that detect the pressure of the vacuum holes Vh in different areas. For example, a guide table 120 includes first and second areas Z1a and Z1b that are separate from each other. The first pressure sensor 151 detects the pressure in the vacuum holes Vh within the first area Z1a, and the second pressure sensor 152 detects the pressure in the vacuum holes Vh within the second area Z1b. In some embodiments, the first and second areas Z1a and Z1b are separated in a second direction Y. For example, the first and second areas Z1a and Z1b are separated by the reference line Px of FIG. 4.

The first and second pressure sensors 151 and 152 detect a tension imbalance in the lamination tape LT. For example, due to warping of a target substrate WF and/or a press roller 130, the lamination tape LT is differently adsorbed in the first and second areas Z1a and Z1b. For example, during attachment of the lamination tape LT to the target substrate WF, the negative pressure detected by the first pressure sensor 151 may be between about −50 kPA and about −70 kPA, while the negative pressure detected by the second pressure sensor 152 may be between about −1 kPa and about −2 kPa. In this manner, tension imbalance in the lamination tape LT can be detected in the second direction Y.

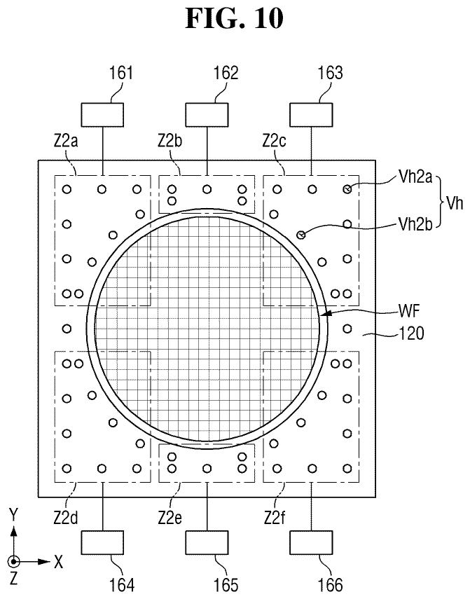

FIG. 10 is a plan view of a laminating device according to some embodiments of the present disclosure. For convenience, repeated descriptions of components described above with reference to FIGS. 1 to 9 may be summarized or omitted.

Referring to FIG. 10, in an embodiment, a plurality of vacuum holes Vh include a plurality of third sub-holes Vh2a and a plurality of fourth sub-holes Vh2b.

The third sub-holes Vh2a are arranged along the circumference of a guide table 120. The fourth sub-holes Vh2b are arranged along the circumference of a target substrate WF or an inner hole 120h. The third sub-holes Vh2a and the fourth sub-holes Vh2b are both symmetrically arranged in a second direction Y.

In some embodiments, in a plan view, each of the third sub-holes Vh2a and/or the fourth sub-holes Vh2b has a circular shape.

In some embodiments, a plurality of pressure sensors 161 to 166 are disposed that are connected to the vacuum holes Vh. The pressure sensors 161 to 166 detect the pressure in the vacuum holes Vh in different areas. For example, the guide table 120 includes third to eighth areas Z2a to Z2f that are separate from each other. The third to fifth areas Z2a to Z2c are sequentially arranged in a first direction X. The sixth to eighth areas Z2d to Z2f are symmetrically arranged with respect to the third to fifth areas Z2a to Z2c in the second direction Y. The pressure sensors 161 to 166 correspond to the third to eighth areas Z2a to Z2f, respectively. The pressure sensors 161 to 166 can detect tension imbalance in a lamination tape LT in both the first and second directions X and Y.

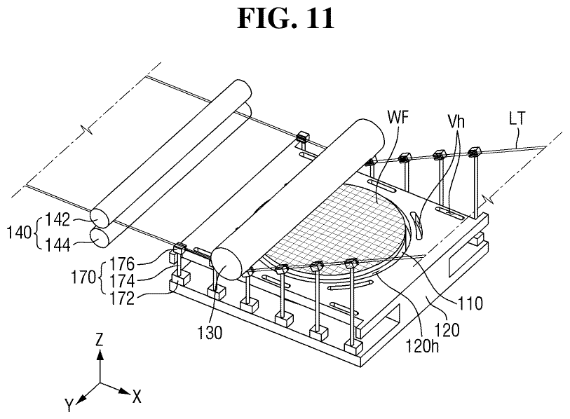

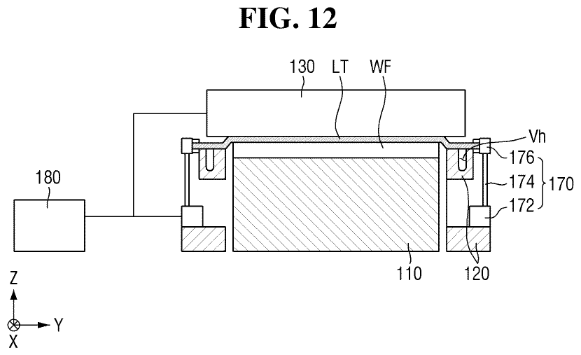

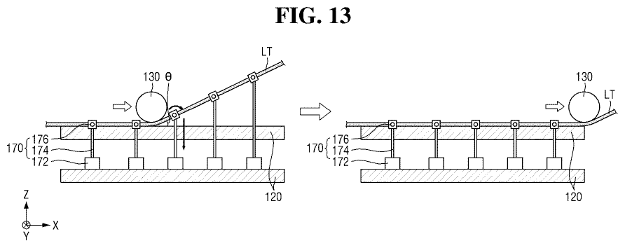

FIG. 11 is a perspective view of a laminating device according to some embodiments of the present disclosure. FIG. 12 is a cross-sectional view of a laminating device of FIG. 11. FIG. 13 are cross-sectional views that illustrate an operation of a laminating device of FIG. 11. For convenience, repeated descriptions of components described above with reference to FIGS. 1 to 10 may be summarized or omitted.

Referring to FIGS. 11 to 13, a laminating device according to some embodiments of the present disclosure further includes clamping members 170.

The clamping members 170 are disposed on a side surface of a guide table 120. The clamping members 170 are fixed to a substrate support 110 and/or the guide table 120. The clamping members 170 clamp both sides of a lamination tape LT in a second direction Y. In some embodiments, a plurality of clamping members 170 are arranged along a first direction X on both sides of the lamination tape LT.

In some embodiments, the clamping members 170 include base parts 172, axis parts 174, and clamping parts 176. The base parts 172 are fixed to the substrate support 110 and/or the guide table 120. The clamping parts 176 clamp the sides of the lamination tape LT. The axis parts 174 connect the base parts 172 and the clamping parts 176. The axis parts 174 can adjust the height of the clamping parts 176 in a third direction Z that intersects, for example, is perpendicular to, the upper surface of a target substrate WF.

During the attachment of the lamination tape LT to the target substrate WF, the clamping members 170 operate in conjunction with a press roller 130. For example, as illustrated in FIG. 13, as the press roller 130 presses the upper surface of the lamination tape LT and moves in the first direction X, the axis parts 174 descend, and the clamping parts 176 rotate. For example, the clamping parts 176 descend and rotate as the press roller 130 moves in the first direction X. The clamping members 170 can more effectively prevent tension imbalance in the lamination tape LT in the second direction Y.

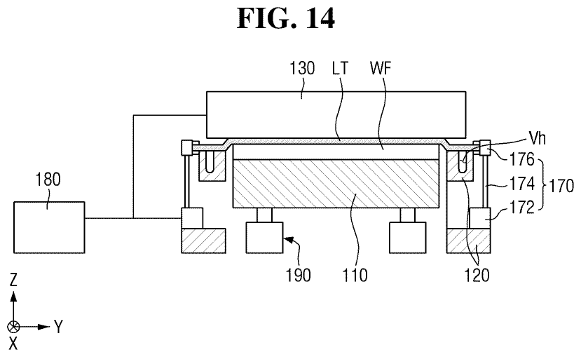

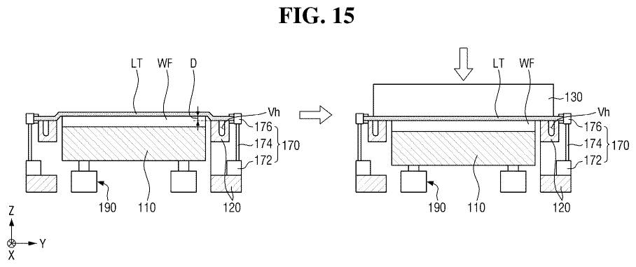

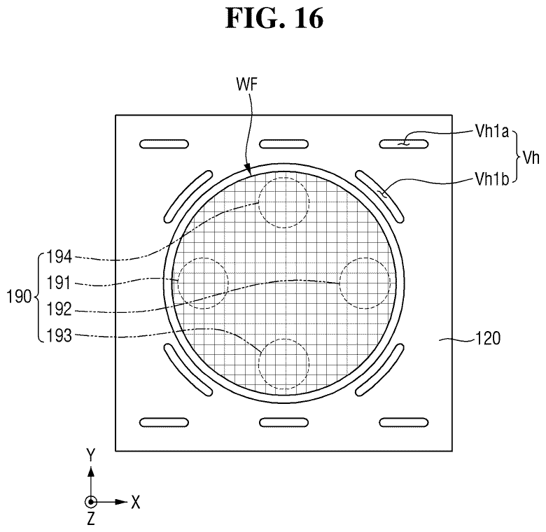

FIG. 14 is a cross-sectional view of a laminating device according to some embodiments of the present disclosure. FIG. 15 is a cross-sectional view of a laminating device of FIG. 14. FIG. 16 are cross-sectional views that illustrate the operation of a laminating device of FIG. 14. For convenience, repeated descriptions of components described above with reference to FIGS. 1 to 13 may be summarized or omitted.

Referring to FIGS. 14 to 16, a laminating device according to some embodiments of the present disclosure further includes an elastic member 190.

The elastic member 190 is disposed below a substrate support 110. For example, the elastic member 190 supports the lower surface of the substrate support 110. The elastic member 190 is elastically operable in a third direction Z.

During the attachment of a lamination tape LT to a target substrate WF, the elastic member 190 can eliminate a height difference D between the upper surface of a guide table 120 and the upper surface of the target substrate WF. For example, as illustrated in FIG. 15, as a press roller 130 presses the upper surface of the lamination tape LT, the elastic member 190 is compressed in the third direction Z, eliminating the height difference D between the upper surfaces of the guide table 120 and the target substrate WF.

The height difference D between the upper surface of the guide table 120 and the upper surface of the target substrate WF transfers the pressure that attaches the lamination tape LT to the target substrate WF. However, the height difference D can cause warping of the target substrate WF and/or the press roller 130, leading to a tension imbalance in the lamination tape LT. The elastic member 190 can effectively prevent a tension imbalance in the lamination tape LT by eliminating the height difference D during the attachment of the lamination tape LT onto the target substrate WF.

In some embodiments, the elastic member 190 detects the pressure applied thereto in the third direction Z. For example, the elastic member 190 includes compression load cells.

In some embodiments, the elastic member 190 disposed below the substrate support 110 includes a plurality of compression load cells 191 to 194. For example, the elastic member 190 includes a first compression load cell 191, a second compression load cell 192, a third compression load cell 193, and a fourth compression load cell 194. The first and second compression load cells 191 and 192 are arranged in the first direction X, and the third and fourth compression load cells 193 and 194 are arranged in the second direction Y. The elastic member 190 can prevent tension imbalance in the lamination tape LT by detecting pressure imbalance in the first direction X and the second direction Y. However, embodiments of the present disclosure are not necessarily limited thereto. In other embodiments, the arrangement and number of compression load cells can vary.

A method of fabricating a semiconductor chip according to some embodiments of the present disclosure will hereinafter be described with reference to FIGS. 1 to 20.

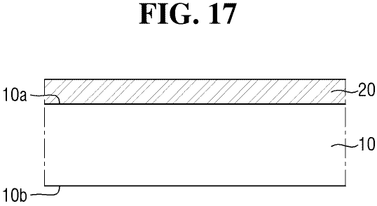

FIGS. 17 to 20 are cross-sectional views that illustrate a method of fabricating a semiconductor chip according to some embodiments of the present disclosure. For convenience, repeated descriptions of components described above with reference to FIGS. 1 to 16 may be summarized or omitted.

Referring to FIG. 17, in an embodiment, a semiconductor device layer 20 is formed on a semiconductor substrate 10.

The semiconductor substrate 10 may be, for example, a bulk silicon or silicon-on-insulator (SOI) substrate. The semiconductor substrate 10 may be a silicon substrate, or may include another material, such as at least one of silicon germanium, indium antimonide, lead telluride compounds, indium arsenide, indium phosphide, gallium arsenide, or gallium antimonide. In some embodiments, the semiconductor substrate 10 includes an epitaxial layer formed on a base substrate.

The semiconductor substrate 10 includes first and second surfaces 10a and 10b that are opposite to each other. The first surface 10a is an active surface on which the semiconductor device layer 20 is formed. For example, the first surface 10a includes conductive areas, such as doped wells. In addition, the first surface 10a may include various device isolation structures, such as insulating areas, such as shallow trench isolations (STIs).

The semiconductor device layer 20 is formed on the first surface 10a of the semiconductor substrate 10. The semiconductor device layer 20 includes various types of individual devices and/or interlayer dielectric films. The individual devices refer to various microelectronic devices, such as metal-oxide-semiconductor field-effect transistors (MOSFETs), such as complementary metal-insulator-semiconductor (CMOS) transistors, system large scale integration (LSI), flash memories, dynamic random-access memories (DRAMs), static random-access memories (SRAMs), electrically erasable programmable read-only memories (EEPROMs), phase-change random-access memories (PRAMs), magnetic random-access memories (MRAMs), resistive random-access memories (RRAMs), CMOS imaging sensors (CISs), image sensors, micro-electro-mechanical systems (MEMSs), active devices, passive devices, etc., but embodiments of the present disclosure are not necessarily limited thereto.

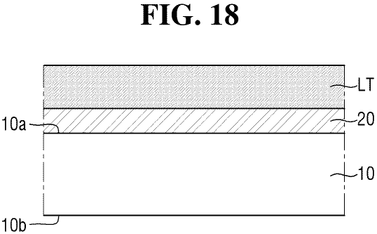

Referring to FIG. 18, in an embodiment, a lamination tape LT is formed on the semiconductor device layer 20.

The lamination tape LT covers the semiconductor device layer 20. The lamination tape LT is formed using any one of the laminating devices described above with reference to FIGS. 1 to 16. For example, the semiconductor substrate 10 and the semiconductor device layer 20 correspond to any one of the target substrates WF described above with reference to FIGS. 1 to 16.

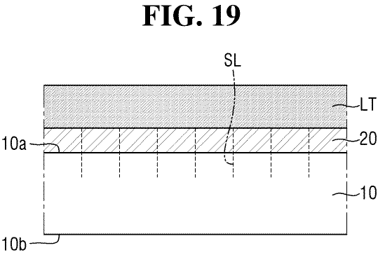

Referring to FIG. 19, in an embodiment, a stealth dicing process is performed on the semiconductor substrate 10 and/or the semiconductor device layer 20.

As the stealth dicing process is performed, scribe lines SL are formed within the semiconductor substrate 10 and/or within the semiconductor device layer 20. The scribe lines SL can include cracks formed within the semiconductor substrate 10 and/or the semiconductor device layer 20.

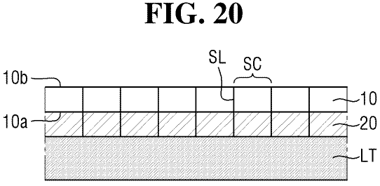

Referring to FIG. 20, a grinding process, such as a back grinding process, is performed on the second surface 10b of the semiconductor substrate 10.

As the grinding process is performed, the thickness of the semiconductor substrate 10 is reduced. In addition, during the grinding process, a plurality of chip areas SC defined by the scribe lines SL are formed. The chip areas SC are separated from each other by the scribe lines SL.

In concluding the detailed description, those skilled in the art will appreciate that many variations and modifications can be made to described embodiments without substantially departing from the principles of the present inventive concept. Therefore, the described embodiments of the disclosure are used in a generic and descriptive sense only and not for purposes of limitation.

What is claimed is:

1. A laminating device, comprising:
a substrate support on which a target substrate is disposed;
a guide table that surrounds a circumference of the target substrate; and
a press roller that attaches a lamination tape by pressing the lamination tape against upper surfaces of the target substrate and the guide table,
wherein the guide table includes a plurality of vacuum holes that adsorb the lamination tape.

2. The laminating device of claim 1, wherein
the press roller presses an upper surface of the lamination tape while moving in a first direction parallel to the upper surface of the target substrate, and
the vacuum holes are symmetrically arranged with respect to a reference line that extends in the first direction and passes through a center of the target substrate.

3. The laminating device of claim 2, further comprising:
clamping members that clamp both sides of the lamination tape in a second direction that is parallel to the upper surface of the target substrate and crosses the first direction.

4. The laminating device of claim 3, wherein the clamping members operate in conjunction with the press roller.

5. The laminating device of claim 1, wherein the vacuum holes include a plurality of first sub-holes that are arranged along a circumference of the guide table, and a plurality of second sub-holes that are arranged along the circumference of the target substrate.

6. The laminating device of claim 1, further comprising:
a pressure sensor that detects pressure in at least some of the vacuum holes.

7. The laminating device of claim 1, wherein the upper surface of the guide table is lower than the upper surface of the target substrate.

8. The laminating device of claim 7, further comprising:
an elastic member disposed below the substrate support and that is compressed by being pressed by the press roller.

9. The laminating device of claim 8, wherein the elastic member includes compression load cells.

10. The laminating device of claim 7, wherein a height difference between the upper surface of the guide table and the upper surface of the target substrate is between 50 μm and 100 μm.

11. A laminating device, comprising:
a substrate support on which a target substrate is disposed;
a guide table that surrounds a circumference of the target substrate;
a press roller that attaches a lamination tape onto upper surfaces of the target substrate and the guide table by pressing an upper surface of the lamination tape while moving in a first direction parallel to the upper surface of the target substrate; and
clamping members that clamp both sides of the lamination tape in a second direction parallel to the upper surface of the target substrate and that crosses the first direction,
wherein
the guide table includes a plurality of vacuum holes that extend from the upper surface of the guide table and provide a negative pressure, and
the clamping members operate in conjunction with the press roller.

12. The laminating device of claim 11, wherein the vacuum holes are symmetrically arranged with respect to a reference line that extends in the first direction and passes through a center of the target substrate.

13. The laminating device of claim 11, wherein
the guide table includes first and second areas that are separate from each other in the second direction,
the laminating device further comprises a first pressure sensor that detects pressure in vacuum holes in the first area and a second pressure sensor that detects pressure in vacuum holes in the second area.

14. The laminating device of claim 11, wherein the clamping members include base parts that are fixed to the substrate support or the guide table, clamping parts that clamp the lamination tape, and driving shafts that connect the base parts and the clamping parts.

15. The laminating device of claim 14, wherein, as the press roller moves in the first direction, the clamping parts descend and rotate.

16. The laminating device of claim 11, wherein the upper surface of the guide table is disposed lower than the upper surface of the target substrate.

17. The laminating device of claim 16, wherein a height difference between the upper surface of the guide table and the upper surface of the target substrate is between 50 μm and 100 μm.

18. The laminating device of claim 16, further comprising:
an elastic member disposed below the substrate support and that is compressed by being pressed by the press roller.

19. The laminating device of claim 18, wherein the elastic member includes compression load cells.

20. A method of fabricating a semiconductor chip, comprising:
providing a semiconductor substrate that includes first and second surfaces that are opposite to each other;
forming a semiconductor device layer on the first surface of the semiconductor substrate;
forming a lamination tape that covers the semiconductor device layer by using a laminating device;
performing a stealth dicing process on the semiconductor substrate and the semiconductor device layer; and
performing a grinding process on the second surface of the semiconductor substrate,
wherein
the laminating device includes a wafer table on which the semiconductor substrate is disposed, a guide table that surrounds a circumference of the semiconductor substrate, and a press roller that attaches a lamination tape by pressing the lamination tape against upper surfaces of the target substrate and the guide table, and
the guide table includes a plurality of vacuum holes that adsorb the lamination tape.
